(19) United States
(12) Patent Application Publication
(10) Pub. No.: US 2014/0239479 A1
(43) Pub. Date: Aug. 28, 2014

(54) MICROELECTRONIC PACKAGE INCLUDING AN ENCAPSULATED HEAT SPREADER

(71) Applicant: Paul R Start, Chandler, AZ (US)

(72) Inventor: Paul R Start, Chandler, AZ (US)

(21) Appl. No.: 13/776,814

(22) Filed: Feb. 26, 2013

(51) Int. Cl. H01L 23/34; H01L 21/56

(52) U.S. Cl. CPC H01L 23/34; H01L 21/56
USPC 257/706; 438/108

(57) ABSTRACT

A microelectronic package of the present description may include a microelectronic interposer having a first surface with an active surface of the at least one microelectronic device electrically attached to the microelectronic interposer first surface. A thermal interface material may be disposed on a back surface of the at least one microelectronic device. A heat spreader, having a first surface and an opposing second surface, may be in thermal contact by its first surface with the thermal interface material. A mold material may be disposed to encapsulate the microelectronic device, the thermal interface material, and the heat spreader, wherein the mold material abuts at least a portion of the microelectronic interposer first surface.

### TECHNICAL FIELD

Embodiments of the present description generally relate to the removal of heat from microelectronic devices, and, more particularly, to a heat spreader encapsulated with a microelectronic device within a microelectronic package.

### BACKGROUND

Higher performance, lower cost, increased miniaturization of integrated circuit components, and greater packaging density of integrated circuits are ongoing goals of the microelectronic industry. As these goals are achieved, microelectronic devices become smaller. Accordingly, the density of power consumption of the integrated circuit components in the microelectronic device has increased, which, in turn, increases the average junction temperature of the microelectronic device. If the temperature of the microelectronic device becomes too high, the integrated circuits of the microelectronic die may be damaged or destroyed. This issue becomes even more critical when multiple microelectronic devices are incorporated in close proximity to one another in a multiple microelectronic device package, also known as a multi-chip package. Thus, thermal transfer solutions, such as integrated heat spreaders, must be utilized to remove heat from the microelectronic devices. However, the difficulty and cost of fabricating current designs for integrated heat spreaders has become an issue for the microelectronic industry.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a side cross-sectional view of a microelectronic system, as known in the art.

FIG. 2 is a side cross-sectional view of attaching a microelectronic device to a microelectronic interposer, according to an embodiment of the present description.

FIG. 3 is a side cross-sectional view of disposing a thermal interface material on the microelectronic device of FIG. 2, according to an embodiment of the present description.

FIG. 4 is a side cross-sectional view of placing a heat spreader in thermal contact with the thermal interface material of FIG. 3, according to an embodiment of the present description.

FIG. 5 is a side cross-sectional view of placing the structure of FIG. 4 within a mold chase, according to an embodiment of the present description.

FIG. 6 is a side cross-sectional view of placing the structure of FIG. 4 within a mold chase, according to another embodiment of the present description.

FIG. 7 is a side cross-sectional view of introducing a mold material into a mold chase of the mold of FIG. 5, according to an embodiment of the present description.

FIG. 8 is a side cross-sectional view of a microelectronic package formed after curing of the mold material, according to an embodiment of the present description.

FIG. 9 is a side cross-sectional view of the microelectronic package of FIG. 8 attached to a microelectronic substrate, according to an embodiment of the present description.

FIG. 10 is a side cross-sectional view of a multi-chip package attached to a microelectronic substrate, according to an embodiment of the present description.

FIG. 11 is a flow chart of a process of fabricating a microelectronic package having an encapsulated heat spreader, according to an embodiment of the present description.

FIG. 12 is an electronic device/system, according to an embodiment of the present description.

### DESCRIPTION OF EMBODIMENTS

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present invention. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

As microelectronic packages become more complex with the incorporation of various microelectronic devices, PoINT (Package on Interposer) devices, package-on-package devices, digital signal controllers, and the like, larger and more complex integrated heat spreaders must be used which may include features such as cavity-within-a-cavity, notches, wings, chamfers, and terraces, as will be understood to those skilled in the art, in order to accommodate the complex microelectronic packages. However, these features and large size increase the difficulty of manufacturing the integrated heat spreader, increases the risk of defects (e.g. tooling marks, corner/edge breaks, and the like), and increases the risk of not meeting design specifications (e.g. corner radii, foot curvature, chamfer dimension, flatness, and the like).

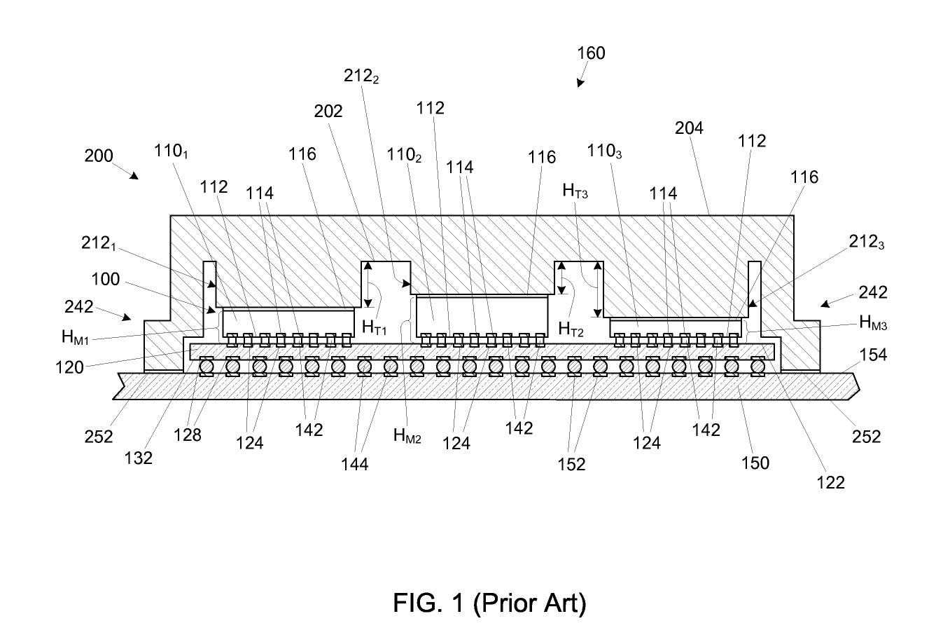

For example, FIG. 1 illustrates microelectronic system having a multi-chip package coupled with a known integrated heat spreader. In the production of microelectronic systems, multi-chip packages are generally mounted on microelectronic substrates, which provide electrical communication routes between the microelectronic packages and external components. As shown in FIG. 1, a multi-chip package 100 may comprise a plurality of microelectronic devices (illustrated as elements 110₁, 110₂, and 110₃), such as microprocessors, chipsets, graphics devices, wireless devices, memory devices, application specific integrated circuits, or the like, attached to a first surface 122 of a microelectronic interposer 120 through a plurality of interconnects 142, respectively, such as reflowable solder bumps or balls, in a configuration generally known as a flip-chip or controlled collapse chip connection (“C4”) configuration. The device-to-interposer interconnects 142 may extend from bond pads 114 on an active surface 112 of each of the microelectronic devices 110₁, 110₂, and 110₃ and bond pads 124 on the microelectronic interposer first surface 122. The microelectronic device bond pads 114 of each of the microelectronic devices 110₁, 110₂, and 110₃, may be in electrical communication with integrated circuitry (not shown) within the microelectronic devices 110₁, 110₂, and 110₃. The microelectronic interposer 120 may include at least one conductive route (not shown) extending therethrough from at least one microelectronic interposer first surface bond pad 124 and at least one microelectronic package bond pad 128 on or proximate a second surface 132 of the microelectronic interposer 120. The microelectronic interposer 120 may reroute a fine pitch (center-to-center distance between the microelectronic device bond pads 114) of the microelectronic device bond pads 114 to a relatively wider pitch of the microelectronic package bond pads 128.

The multi-chip package 100 may be attached to a microelectronic substrate 150, such as printed circuit board, a motherboard, and the like, through a plurality of interconnects 144, such as reflowable solder bumps or balls. The package-to-substrate interconnects 144 may extend between the microelectronic package bond pads 128 and substantially mirror-image bond pads 152 on a first surface 154 of the microelectronic substrate 150. The microelectronic substrate bond pads 152 may be in electrical communication with conductive routes (not shown) within the microelectronic substrate 150, which may provide electrical communication routes to external components (not shown).

Both the microelectronic interposer 120 and the microelectronic substrate 150 may be primarily composed of any appropriate material, including, but not limited to, bismaleimine triazine resin, fire retardant grade 4 material, polyimide materials, glass reinforced epoxy matrix material, and the like, as well as laminates or multiple layers thereof. The microelectronic interposer conductive routes (not shown) and the microelectronic substrate conductive routes (not shown) may be composed of any conductive material, including but not limited to metals, such as copper and aluminum, and alloys thereof. As will be understood to those skilled in the art, microelectronic interposer conductive routes (not shown) and the microelectronic substrate conductive routes (not shown) may be formed as a plurality of conductive traces (not shown) formed on layers of dielectric material (constituting the layers of the microelectronic substrate material), which are connected by conductive vias (not shown).

The package-to-substrate interconnects 144 can be made of any appropriate material, including, but not limited to, solders materials. The solder materials may be any appropriate material, including but not limited to, lead/tin alloys, such as 63% tin/37% lead solder, and high tin content alloys (e.g. 90% or more tin), such as tin/bismuth, eutectic tin/silver, ternary tin/silver/copper, eutectic tin/copper, and similar alloys. When the multi-chip package 100 is attached to the microelectronic substrate 150 with package-to-substrate interconnects 144 made of solder, the solder is reflowed, either by heat, pressure, and/or sonic energy to secure the solder between the microelectronic package bond pads 128 and the microelectronic substrate bond pads 152.

As further illustrated in FIG. 1, an integrated heat spreader 200 may be in thermal contact with the multi-chip package 100, to form a microelectronic system 160. The integrated heat spreader 200 may be made of any appropriate thermally conductive material, such a metals and alloys, including, but not limited to, copper, aluminum, and the like.

The integrated heat spreader 200 may have a first surface 202 and an opposing second surface 204, wherein the integrated heat spreader 200 includes a plurality terraces (illustrated as elements 212₁, 212₂, and 212₃) extending from the integrated heat spreader second surface 204. As illustrated, the integrated heat spreader terraces 212₁, 212₂, and 212₃ may have differing heights H_{T1}, H_{T2}, and H_{T3} extending from the integrated heat spreader second surface 204 to compensate for differing heights H_{M1}, H_{M2}, and H_{M3} of the microelectronic devices 110₁, 110₂, and 110₃ (i.e. the distance between the microelectronic substrate first surface 154 and a back surface 116 of each microelectronic devices 110₁, 110₂, and 110₃), respectively, in order to make thermal contact therebetween. A thermal interface material 232, such as a thermally conductive grease, may be disposed between each integrated heat spreader terrace 212₁, 212₂, and 212₃ and its respective back surface 116 of each microelectronic device 110₁, 110₂, and 110₃ to facilitate heat transfer therebetween.

The integrated heat spreader 200 may include at least one footing 242 extending between the integrated heat spreader second surface 204 and the microelectronic substrate 150, wherein the integrated heat spreader footing 242 may be attached to the microelectronic substrate first surface 154 with an adhesive material 244.

As will be understood to those skilled in the art, the fabrication of the integrated heat spreader 200 requires expensive stamping equipment able to achieve high tonnage stamping forces in order to form complex elements, such as illustrate integrated heat spreader terraces 212₁, 212₂, and 212₃. For example, for a copper integrated heat spreader, such as oxygen-free copper (99.99%), a 600 ton stamping machine may be required to form such integrated head spreader terraces, especially as heat spreader size increases. Furthermore, the attachment of the integrated heat spreader footing 242 to the microelectronic substrate first surface 154 with the adhesive material 244 requires space on the microelectronic substrate first surface 154, which, as microelectronic structure become smaller, puts pressure on placement accuracy, limits the ability to accommodate certain package design, and risks delamination of the adhesive material 244, as will be understood to those skilled in the art.

Embodiments of the present description relate to a microelectronic package including a microelectronic interposer having a first surface with an active surface of at least one microelectronic device electrically attached to the microelectronic interposer first surface. A thermal interface material may be disposed on a back surface of the microelectronic device. A heat spreader, having a first surface and an opposing second surface, may be in thermal contact by its first surface with the thermal interface material. A mold material may be disposed to encapsulate the microelectronic device, the thermal interface material, and the heat spreader, wherein the mold material abuts at least a portion of the microelectronic interposer first surface.

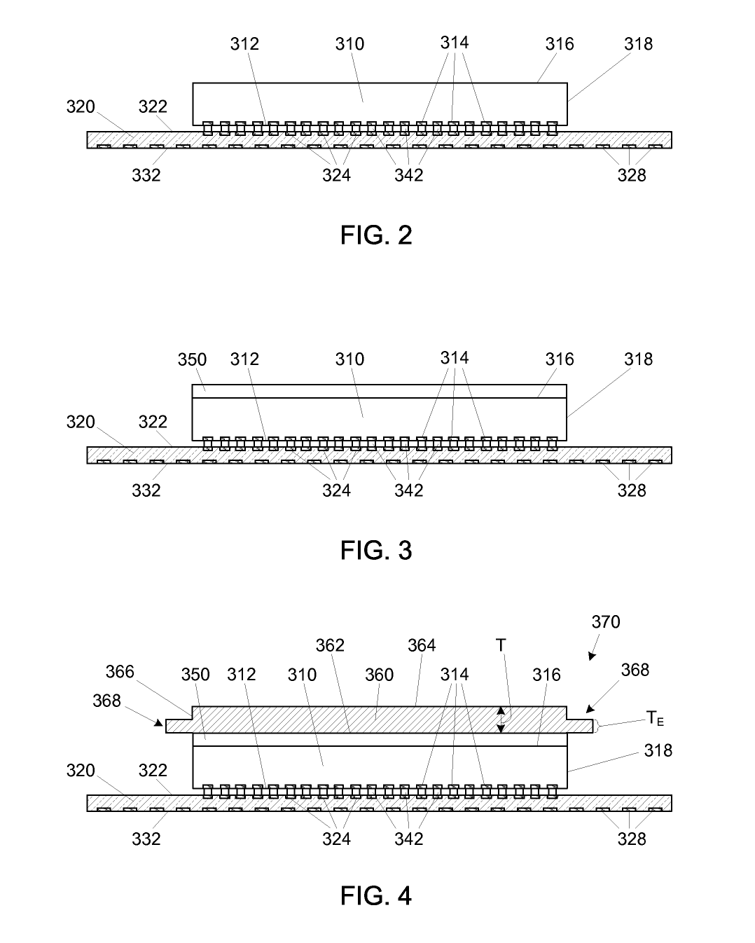

FIGS. 2-8 illustrate a process of fabricating a microelectronic package having an encapsulated heat spreader according to one embodiment of the present description. As shown in FIG. 2, a microelectronic device 310, such as microprocessors, chipsets, graphics devices, wireless devices, memory devices, application specific integrated circuits, or the like, may be attached to a first surface 322 of a microelectronic interposer 320 through a plurality of interconnects 342, respectively, such as reflowable solder bumps or balls, in a configuration generally known as a flip-chip or controlled collapse chip connection (“C4”) configuration. The device-to-interposer interconnects 342 may extend from bond pads 314 on an active surface 312 of the microelectronic device 310 and bond pads 324 on the microelectronic interposer first surface 322. The microelectronic device bond pads 314 may be in electrical communication with integrated circuitry (not shown) within the microelectronic device 310. The microelectronic interposer 320 may include at least one conductive route (not shown) extending therethrough from at least one microelectronic interposer first surface bond pad 324 and at least one bond pad 328 on or proximate a second surface 332 of the microelectronic interposer 320. The microelectronic interposer 320 may reroute a fine pitch (center-to-center distance between the microelectronic device bond pads 314) of the microelectronic device bond pads 314 to a relatively wider pitch of the microelectronic interposer second surface bond pads 328. As further shown in FIG. 2, at least one microelectronic device sidewall 318 may be defined between the microelectronic device active surface 312 and an opposing microelectronic device back surface 316.

As shown in FIG. 3, a thermal interface material 350 may be disposed on the microelectronic device back surface 316. As shown in FIG. 4, a heat spreader 360 may be placed such that a first surface 362 of the heat spreader 360 is in contact with the thermal interface material 350 to form an intermediate assembly 370. The thermal interface material 350 may be used for achieve appropriate thermal contact between the heat spreader 360 and the microelectronic device 310, and may be any appropriate material, including, but not limited to, filled polymeric materials (such as silicone-based gels, flexible epoxies, acetal, acrylic, cellulose acetate, polyethylene, polystryrene, vinyl, nylon, or combinations thereof), filled elastomer materials (such as polybutadiene, isobutylene, isoprene, acrylonitrile, and the like), and carbon-based materials (such as carbon nanotube filler in silicon matrix). In one embodiment, the thermal interface material 350 may be a vertically aligned carbon based material, such as a composite of vertically aligned graphite sheets in an elastomeric matrix. The heat spreader 360 may be made of any appropriate thermally conductive material, including, but not limited to metals, such as copper, aluminum, nickel, gold, silver, alloys thereof, thermally conductive ceramics, and the like. In one embodiment, the heat spreader 360 may comprise a copper core plated with nickel.

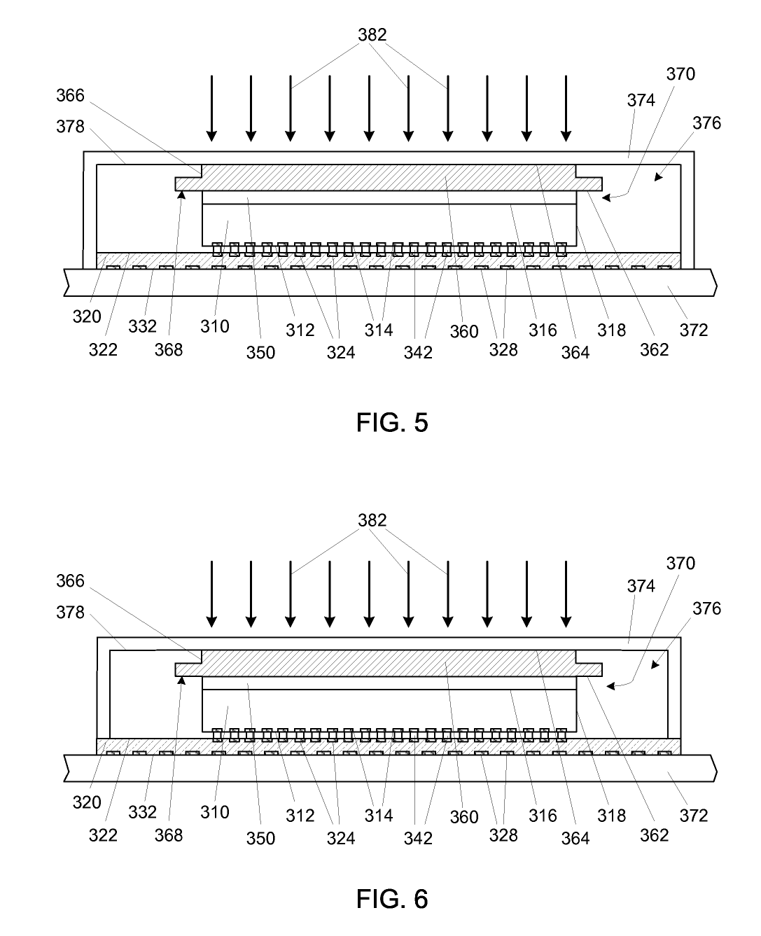

As shown in FIG. 5, the intermediate assembly 370 may be placed on a support plate 372 and a mold 374 may be placed such that it contacts and seals against the support plate 372, and such that a chase 376 of the mold 374 surrounds at least a portion of each of the microelectronic device 310, the thermal interface material 350, and the heat spreader 360. A wall 378 of the mold 374 may contact a heat spreader second surface 364, which may oppose the heat spreader first surface 362. A load (illustrated by arrows 382 may be applied to the mold 374 such that the thermal interface material 350 may be compressed, which may improve the interfacial thermal resistance when a pressure sensitive thermal interface material is used, as will be understood to those skilled in the art. It is understood that although the mold 362 is shown contacting the support plate 372, the mold 362 may simply contact and seal against the microelectronic interposer first surface 322, as shown in FIG. 6.

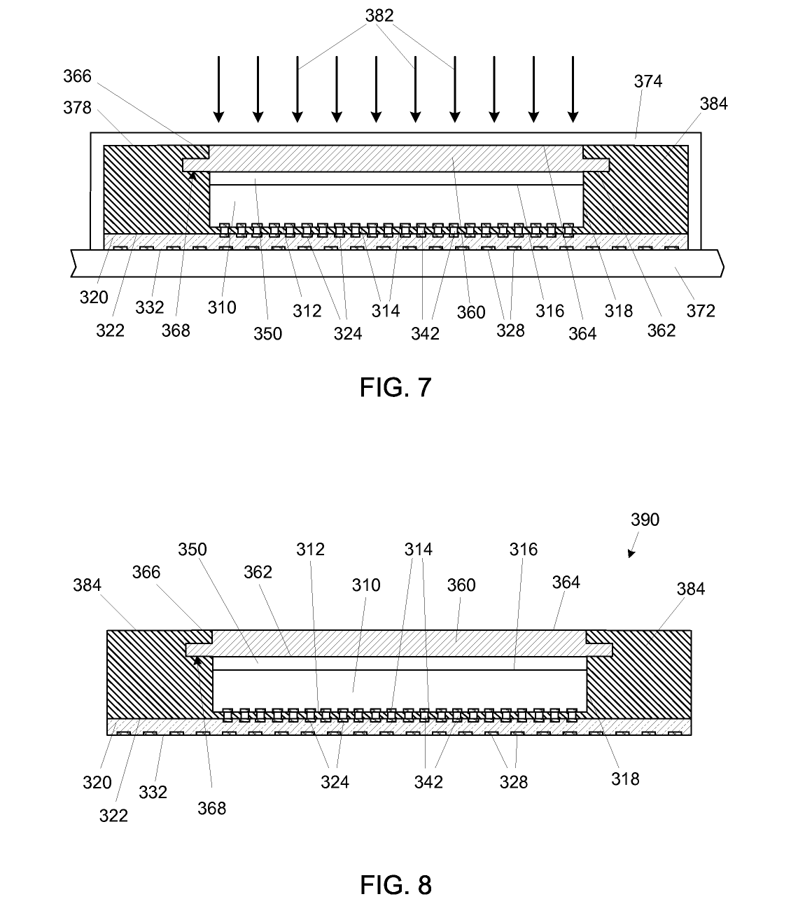

As shown in FIG. 7, a mold material 384 may be introduced into the mold chase 376 (see FIG. 6) to envelop at least a portion of each of the microelectronic device 310, the thermal interface material 350, and the heat spreader 360. In one embodiment, the mold material 382 may be sufficiently viscous to envelop the device-to-interposer interconnects 342. If the mold material 382 is not sufficiently viscous to extend between the microelectronic device active surface 312 and the microelectronic interposer first surface 322 to envelop the device-to-interposer interconnects 342, an underfill material (not shown) may be dispensed between the microelectronic device active surface 312 and the microelectronic substrate first surface 322 prior to the molding process, as will be understood to those skilled in the art. The mold material 382 may be any appropriate material, including, but not limited to epoxy materials and filled epoxy materials. The mold material 382 may be also thermally conductive, such that the mold material 382 itself may assist in heat dissipation.

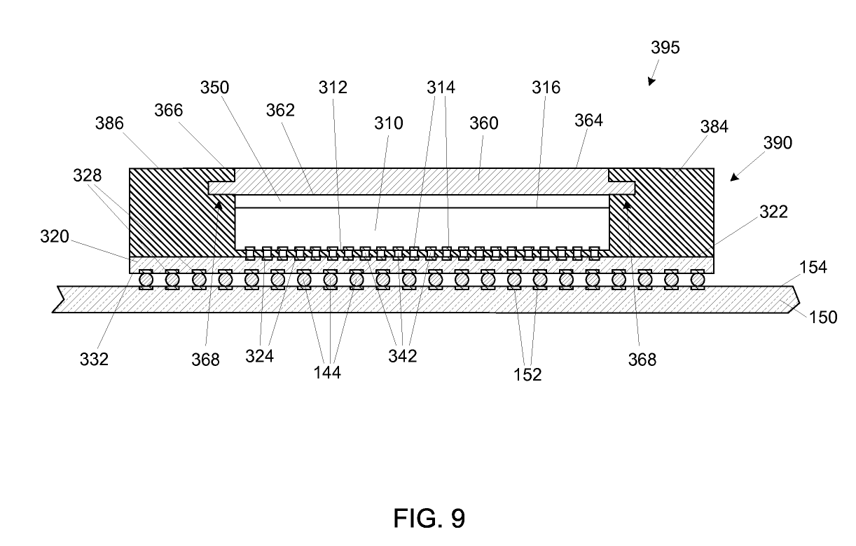

After the mold material 384 has cured/hardened, the mold 372 may be removed to formed a microelectronic package 390, shown in FIG. 8. Following removal from the mold, further curing of the mold material may be performed. Referring back to FIG. 5, placing the mold wall 378 to be planar with the heat spreader second surface 364 may result in the formation of a mold material back surface 386 which is substantially planar to the heat spreader second surface 364 and expose the heat spreader second surface 364 from the mold material 382, as shown in FIG. 8. As will be understood to those skilled in the art, exposing the heat spreader second surface 364 allows for contacting a secondary heat removal mechanism, such as a finned heat dissipation device, a heat pipe, or the like, thereto.

As shown in FIGS. 4-8, at least one extension or tab 368 may extend from at least one side 366 of the heat spreader 360, wherein the at least one heat spreader side 366 may be defined to extend between the heat spreader first surface 362 and the heat spreader second surface 364. As shown in FIG. 4, a thickness T_{E} of the extension 368 may be less than a thickness T of the heat spreader 360 defined between the heat spreader first surface 362 and the heat spreader second surface 364. As shown in FIG. 8, the mold material 382 may substantially surround the extension(s) 368. The extension(s) 368 may assist in preventing the heat spreader 360 from delaminating from the mold material 382.

As shown in FIG. 9, the microelectronic package 390 may be attached to the microelectronic substrate 150, such as printed circuit board, a motherboard, and the like, through the plurality of interconnects 144, such as reflowable solder bumps or balls, as discussed and described with regard to FIG. 1, to form a microelectronic structure 395. The package-to-substrate interconnects 144 may extend between at least one the microelectronic interposer second surface bond pads 328 and substantially mirror-image bond pads 152 on a first surface 154 of the microelectronic substrate 150. The microelectronic substrate bond pads 152 may be in electrical communication with conductive routes (not shown) within the microelectronic substrate 150, which may provide electrical communication routes to external components (not shown).

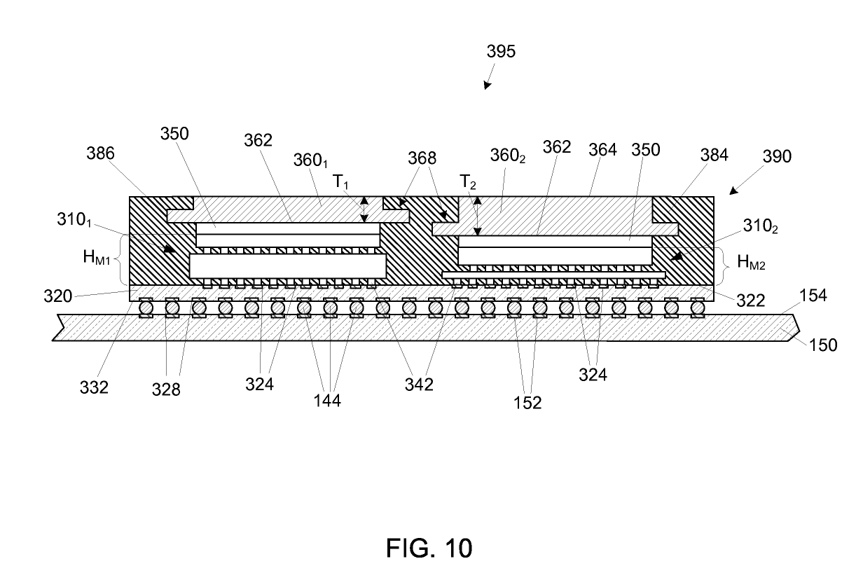

As illustrated in FIG. 10, the process described with regard to a single microelectronic device package shown in FIGS. 2-9 may be applied to multi-chip packages. As will be understood to those skilled in the art, any appropriate number of microelectronic devices (shown as elements 310₁ and 310₂) may be electrically attached to the microelectronic interposer 320. The microelectronic devices 310₁ and 310₂ may have differing heights H_{M1} and H_{M2}, respectively. Thus, each heat spreader 360₁ and 360₂ for each microelectronic device 310₁ and 310₂ may each have a thickness T₁ and T₂, respectively, which compensates for the differing heights H_{M1} and H_{M2}, such that the second surfaces 364 of each heat spreader 360₁ and 360₂ may be substantially planar with the mold material back surface 386. Although the microelectronic devices 310₁ and 310₂ are shown as a stacked package and a package-on-interposer (PoINT) device, respectively, the microelectronic devices 310₁ and 310₂ may be any appropriate microelectronic device, passive or active, as will be understood to those skilled in the art.

As will be understood to those skilled in the art, the embodiments of the present description may free up space on the microelectronic substrate that would have otherwise been used by the attachment of the integrated heat spreader to the microelectronic substrate, as described with regard to FIG. 1, and eliminates the process of accurately placing the integrated heat spreader, which may enable reduced form factors and lower costs. Further, the embodiments of the present description allow for accommodation of a variety of microelectronic devices without the need to fabricate complex integrated heat spreaders, as the fabrication of the heat spreaders of the present description may only entail simple cutting, trimming, and/or plating process, which may eliminate the need for expensive tooling. Moreover, by tailoring mold material properties and eliminating design factors, such as integrated heat spreader overhang, improved package thermal performance may be enabled through better coupling of the heat spreader to the microelectronic package, and through increased compressive load on the thermal interface, which may lower interfacial thermal resistance. Additionally, package warpage may be reduced or controlled through targeting proper mold material properties and through design in the extent of mold coverage. Similar characteristics may also provide benefits of more uniform load distribution in socketing, as will be understood to those skilled in the art. Thus, embodiments of the present description may eliminate many of the current constraints for integrated heat spreader and microelectronic package design, assembly, and manufacturing, and may lower the risk of key failure modes relative to the current integrated heat spreader processes and materials. As such, embodiment of the present description may lead to significant cost savings by enabling simplified flexible designs, reduced microelectronic substrate sizes, and lower thermal solution costs.

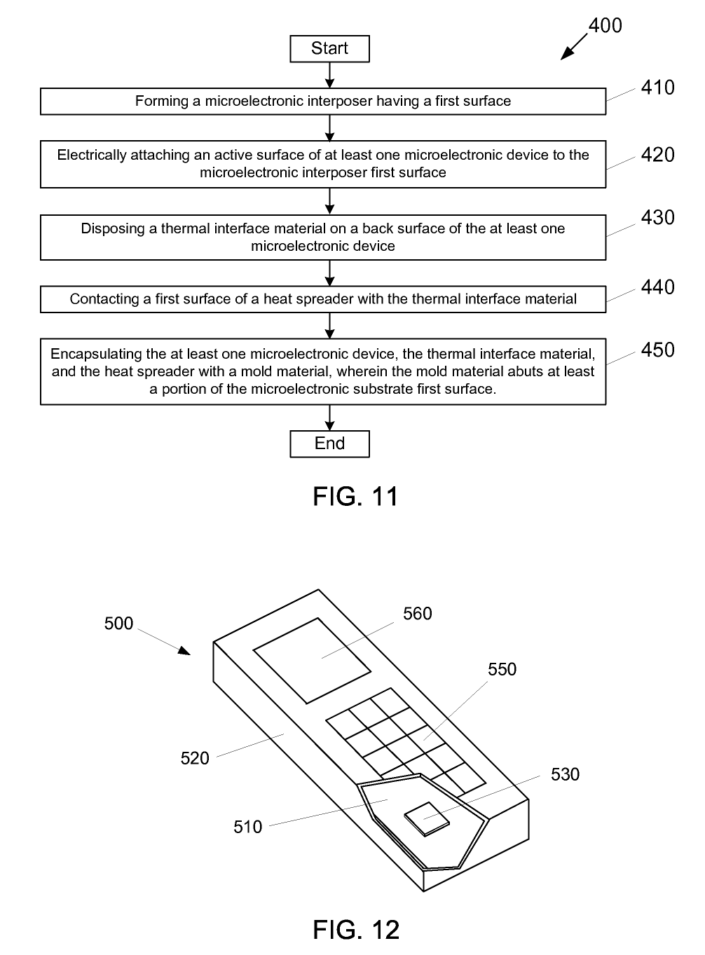

FIG. 11 is a flow chart of a process 400 of fabricating a microelectronic package according to an embodiment of the present description, such as illustrated in FIGS. 2-10. As set forth in block 410, a microelectronic interposer, having a first surface, may be formed. An active surface of at least one microelectronic device may be electrically attached to the microelectronic substrate first surface, as set forth in block 420. As set forth in block 430, a thermal interface material may be disposed on a back surface of the at least one microelectronic device. A first surface of a heat spreader may be placed in thermal contact with the thermal interface material, as set forth in block 440. As set forth in block 450, the at least one microelectronic device, the thermal interface material, and the heat spreader may be encapsulated with a mold material, wherein the mold material abuts at least a portion of the microelectronic substrate first surface.

FIG. 12 illustrates an embodiment of an electronic system/device 500, such as a portable computer, a desktop computer, a mobile telephone, a digital camera, a digital music player, a web tablet/pad device, a personal digital assistant, a pager, an instant messaging device, or other devices. The electronic system/device 500 may be adapted to transmit and/or receive information wirelessly, such as through a wireless local area network (WLAN) system, a wireless personal area network (WPAN) system, and/or a cellular network. The electronic system/device 500 may include a microelectronic motherboard or substrate 510 disposed within a device housing 520. The microelectronic motherboard/substrate 510 may have various electronic components electrically coupled thereto including a microelectronic package 530 having an encapsulated heat spreader, as described in the embodiments of the present description. The microelectronic motherboard/substrate 510 may be attached to various peripheral devices including an input device 550, such as a keypad, and a display device 560, such an LCD display. It is understood that the display device 560 may also function as the input device, if the display device 560 is touch sensitive.

It is understood that the subject matter of the present description is not necessarily limited to specific applications illustrated in FIGS. 1-12. The subject matter may be applied to other microelectronic device and assembly applications, as well as any appropriate heat removal application, as will be understood to those skilled in the art.

The following examples pertain to further embodiments, wherein Example 1 is a microelectronic structure, comprising a microelectronic interposer having a first surface; at least one microelectronic device having an active surface and an opposing back surface, wherein the at least one microelectronic device active surface is electrically attached to the microelectronic substrate first surface; a thermal interface material disposed on the at least one microelectronic device back surface; a heat spreader having a first surface and an opposing second surface, wherein the heat spreader first surface thermally contacts the thermal interface material; and a mold material encapsulating the at least one microelectronic device, the thermal interface material, and the heat spreader, wherein the mold material abuts at least a portion of the microelectronic interposer first surface, and wherein the heat spreader second surface is exposed through mold material.

In Example 2, the subject matter of Example 1 can optionally include the mold material extending between the interposer first surface and the microelectronic device active surface.

In Example 3, the subject matter of any one of Examples 1-2 can optionally include the heat spreader second surface substantially planar to a back surface of the mold material.

In Example 4, the subject matter of any one of Examples 1-3 can optionally include at least one extension extending from at least one side of the heat spreader.

In Example 5, the subject matter of Examples 4 can optionally include a thickness of the extension being less than a thickness between the heat spreader first surface and the heat spreader second surface.

In Example 6, the subject matter of any one of Examples 4 and 5 can optionally include the at least one extension is substantially surrounded by the mold material.

In Example 7, the subject matter of any one of Examples 1-6 can optionally include a microelectronic substrate electrically connected to the microelectronic interposer.

In Example 8, the subject matter of any one of Examples 1-7 can optionally include the at least one microelectronic device comprises a plurality of microelectronic devices, wherein one of the plurality of microelectronic devices has a height greater than a height of another of the plurality of microelectronic devices, wherein a heat spreader in thermal contact with the one of the plurality has a thickness differing from the thickness of the heat spreader in thermal contact with another of the plurality of microelectronic device, and wherein the differing heat spreader thickness compensates for the differing heights of the one of the plurality of microelectronic devices and the another of the plurality of microelectronic devices, such that the second surfaces of the heat surfaces are substantially planar.

In Example 9, a method of forming a microelectronic package may comprise forming a microelectronic interposer having a first surface; electrically attaching an active surface of at least one microelectronic device to the microelectronic interposer first surface; disposing a thermal interface material on a back surface of the at least one microelectronic device; contacting a first surface of a heat spreader with the thermal interface material; and encapsulating the at least one microelectronic device, the thermal interface material, and the heat spreader with a mold material, wherein the mold material abuts at least a portion of the microelectronic substrate first surface, and wherein the heat spreader second surface is exposed through the mold material.

In Example 10, the subject matter of Example 9 can optionally include disposing the mold material between the interposer first surface and the microelectronic device active surface.

In Example 11, the subject matter of any one of Examples 9-11 can optionally include forming a back surface of the mold material wherein the heat spreader second surface is substantially planar to the mold material back surface.

In Example 12, the subject matter of any one of Examples 9-12 can optionally include at least one extension extending from at least one side of the heat spreader.

In Example 13, the subject matter of Example 12 can optionally include a thickness of the extension being less than a thickness between the heat spreader first surface and the heat spreader second surface.

In Example 14, the subject matter of any one of Examples 12 and 13 can optionally include encapsulating the at least one extension with the mold material.

In Example 15, the subject matter of any one of Examples 9-14 can optionally include electrically connecting the microelectronic substrate to the microelectronic interposer.

In Example 16, the subject matter of any one of Examples 9-15 can optionally include the at least one microelectronic device comprises a plurality of microelectronic devices, wherein one of the plurality of microelectronic devices has a height greater than a height of another of the plurality of microelectronic devices, wherein a heat spreader in thermal contact with the one of the plurality has a thickness differing from the thickness of the heat spreader in thermal contact with another of the plurality of microelectronic device, and wherein the differing heat spreader thickness compensates for the differing heights of the one of the plurality of microelectronic devices and the another of the plurality of microelectronic devices, such that the second surfaces of the heat surfaces are substantially planar.

In Example 17, the subject matter of any one of Examples 9-16 can optionally include placing the at least one microelectronic device, the thermal interface material, and the heat spreader within a mold; introducing a mold material into the mold; curing the mold material; and removing the mold.

In Example 18, the subject matter of any one of Examples 9-17 can optionally include sealing the mold against the microelectronic interposer first surface.

In Example 19, the subject matter of any one of Examples 9-17 can optionally include placing the at least one microelectronic device, the thermal interface material, and the heat spreader on a support plate, and sealing the mold against the support substrate.

In Example 20, the subject matter of any one of Examples 9-19 can optionally include applying a load to the mold.

In Example 21, an electronic system may include a housing; a microelectronic substrate disposed within the housing; a microelectronic interposer having a first surface and an opposing second surface, wherein the microelectronic interposer second surface is electrically connected to the microelectronic substrate; at least one microelectronic device having an active surface and an opposing back surface, wherein the at least one microelectronic device active surface is electrically attached to the microelectronic substrate first surface; a thermal interface material disposed on the at least one microelectronic device back surface; a heat spreader having a first surface and an opposing second surface, wherein the heat spreader first surface thermally contacts the thermal interface material; and a mold material encapsulating the at least one microelectronic device, the thermal interface material, and the heat spreader, wherein the mold material abuts at least a portion of the microelectronic interposer first surface, and wherein the heat spreader second surface is exposed through mold material.

In Example 22, the subject matter of Examples 21 can optionally include the mold material extending between the interposer first surface and the microelectronic device active surface.

In Example 23, the subject matter of any one of Examples 21-22 can optionally include the heat spreader second surface substantially planar to a back surface of the mold material.

In Example 24, the subject matter of any one of Examples 21-23 can optionally include at least one extension extending from at least one side of the heat spreader.

In Example 25, the subject matter of Example 24 can optionally include a thickness of the extension being less than a thickness between the heat spreader first surface and the heat spreader second surface.

In Example 26, the subject matter of any one of Examples 24 and 25 can optionally include the at least one extension substantially surrounded by the mold material.

In Example 27, the subject matter of any one of Examples 21-26 can optionally include the at least one microelectronic device comprises a plurality of microelectronic devices, wherein one of the plurality of microelectronic devices has a height greater than a height of another of the plurality of microelectronic devices, wherein a heat spreader in thermal contact with the one of the plurality has a thickness differing from the thickness of the heat spreader in thermal contact with another of the plurality of microelectronic device, and wherein the differing heat spreader thickness compensates for the differing heights of the one of the plurality of microelectronic devices and the another of the plurality of microelectronic devices, such that the second surfaces of the heat surfaces are substantially planar.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A microelectronic structure, comprising:
a microelectronic interposer having a first surface;
at least one microelectronic device having an active surface and an opposing back surface, wherein the at least one microelectronic device active surface is electrically attached to the microelectronic substrate first surface;
a thermal interface material disposed on the at least one microelectronic device back surface;
a heat spreader having a first surface and an opposing second surface, wherein the heat spreader first surface thermally contacts the thermal interface material; and
a mold material encapsulating the at least one microelectronic device, the thermal interface material, and the heat spreader, wherein the mold material abuts at least a portion of the microelectronic interposer first surface, and wherein the heat spreader second surface is exposed through the mold material.

2. The microelectronic structure of claim 1, wherein the mold material extends between the interposer first surface and the microelectronic device active surface.

3. The microelectronic structure of claim 1, wherein the heat spreader second surface is substantially planar to a back surface of the mold material.

4. The microelectronic structure of claim 1, further including at least one extension extending from at least one side of the heat spreader.

5. The microelectronic structure of claim 4, wherein a thickness of the extension is less than a thickness between the heat spreader first surface and the heat spreader second surface.

6. The microelectronic structure of claim 4, wherein the at least one extension is substantially surrounded by the mold material.

7. The microelectronic structure of claim 1, further including a microelectronic substrate electrically connected to the microelectronic interposer.

8. The microelectronic structure of claim 1, wherein the at least one microelectronic device comprises a plurality of microelectronic devices, wherein one of the plurality of microelectronic devices has a height greater than a height of another of the plurality of microelectronic devices, wherein a heat spreader in thermal contact with the one of the plurality has a thickness differing from the thickness of the heat spreader in thermal contact with another of the plurality of microelectronic device, and wherein the differing heat spreader thickness compensates for the differing heights of the one of the plurality of microelectronic devices and the another of the plurality of microelectronic devices, such that the second surfaces of the heat surfaces are substantially planar.

9. A method of forming a microelectronic package, comprising:
forming a microelectronic interposer having a first surface;
electrically attaching an active surface of at least one microelectronic device to the microelectronic interposer first surface;
disposing a thermal interface material on a back surface of the at least one microelectronic device;
contacting a first surface of a heat spreader with the thermal interface material; and
encapsulating the at least one microelectronic device, the thermal interface material, and the heat spreader with a mold material, wherein the mold material abuts at least a portion of the microelectronic substrate first surface, and wherein the heat spreader second surface is exposed through the mold material.

10. The method of claim 9, wherein encapsulating the at least one microelectronic device, the thermal interface material, and the heat spreader with a mold material further includes disposing the mold material between the interposer first surface and the microelectronic device active surface.

11. The method of claim 9, wherein encapsulating the at least one microelectronic device, the thermal interface material, and the heat spreader with a mold material further includes forming a back surface of the mold material wherein the heat spreader second surface is substantially planar to the mold material back surface.

12. The method of claim 9, wherein contacting the first surface of a heat spreader with the thermal interface material further comprises contacting the first surface of a heat spreader with the thermal interface material, wherein the heat spreader includes at least one extension extending from at least one side of the heat spreader.

13. The method of claim 12, wherein a thickness of the extension is less than a thickness between the heat spreader first surface and the heat spreader second surface.

14. The method of claim 12, further includes encapsulating the at least one extension with the mold material.

15. The method of claim 9, further electrically connecting the microelectronic substrate to the microelectronic interposer.

16. The method of claim 9, wherein the at least one microelectronic device comprises a plurality of microelectronic devices, wherein one of the plurality of microelectronic devices has a height greater than a height of another of the plurality of microelectronic devices, wherein a heat spreader in thermal contact with the one of the plurality has a thickness differing from the thickness of the heat spreader in thermal contact with another of the plurality of microelectronic device, and wherein the differing heat spreader thickness compensates for the differing heights of the one of the plurality of microelectronic devices and the another of the plurality of microelectronic devices, such that the second surfaces of the heat surfaces are substantially planar.

17. The method of claim 9, wherein encapsulating the at least one microelectronic device, the thermal interface material, and the heat spreader with the mold material comprises:
placing the at least one microelectronic device, the thermal interface material, and the heat spreader within a mold;
introducing a mold material into the mold;
curing the mold material; and
removing the mold.

18. The method of claim 17, further including sealing the mold against the microelectronic interposer first surface.

19. The method of claim 17, wherein placing the at least one microelectronic device, the thermal interface material, and the heat spreader within a mold comprising placing the at least one microelectronic device, the thermal interface material, and the heat spreader on a support plate, and sealing the mold against the support plate.

20. The method of claim 17, further including applying a load to the mold.

21. An electronic system, comprising:
a housing;
a microelectronic substrate disposed within the housing;
a microelectronic interposer having a first surface and an opposing second surface, wherein the microelectronic interposer second surface is electrically connected to the microelectronic substrate;
at least one microelectronic device having an active surface and an opposing back surface, wherein the at least one microelectronic device active surface is electrically attached to the microelectronic substrate first surface;
a thermal interface material disposed on the at least one microelectronic device back surface;
a heat spreader having a first surface and an opposing second surface, wherein the heat spreader first surface thermally contacts the thermal interface material; and
a mold material encapsulating the at least one microelectronic device, the thermal interface material, and the heat spreader, wherein the mold material abuts at least a portion of the microelectronic interposer first surface, and wherein the heat spreader second surface is exposed through the mold material.

22. The electronic system of claim 21, wherein the mold material extends between the interposer first surface and the microelectronic device active surface.

23. The electronic system of claim 21, wherein the heat spreader second surface is substantially planar to a back surface of the mold material.

24. The electronic system of claim 21, further including at least one extension extending from at least one side of the heat spreader.

25. The electronic system of claim 24, wherein a thickness of the extension is less than a thickness between the heat spreader first surface and the heat spreader second surface.

26. The electronic system of claim 24, wherein the at least one extension is substantially surrounded by the mold material.

27. The electronic system of claim 21, wherein the at least one microelectronic device comprises a plurality of microelectronic devices, wherein one of the plurality of microelectronic devices has a height greater than a height of another of the plurality of microelectronic devices, wherein a heat spreader in thermal contact with the one of the plurality has a thickness differing from the thickness of the heat spreader in thermal contact with another of the plurality of microelectronic device, and wherein the differing heat spreader thickness compensates for the differing heights of the one of the plurality of microelectronic devices and the another of the plurality of microelectronic devices, such that the second surfaces of the heat surfaces are substantially planar.
